(19) United States
(12) Patent Application Publication
(10) Pub. No.: US 2022/0240413 A1
(43) Pub. Date: Jul. 28, 2022

(54) A COOLING UNIT FOR COOLING A HEAT-GENERATING COMPONENT AND A METHOD THEREFOR

(71) Applicant: Telefonaktiebolaget LM Ericsson (publ), Stockholm (SE)

(72) Inventors: Samir SAAIDI, Stockholm (SE); Mikkel MYHRE, Järfälla (SE); Mariam JARAHNEJAD, Stockholm (SE)

(73) Assignee: Telefonaktiebolaget LM Ericsson (publ), Stockholm (SE)

(21) Appl. No.: 17/617,708

(22) PCT Filed: Jun. 10, 2019
(86) PCT No.: PCT/SE2019/050536

§ 371 Date: Dec. 9, 2021

(51) Int. Cl. H05K 7/20

(52) U.S. Cl. CPC H05K 7/20172; H05K 7/20409; H05K 7/20154; H05K 7/20145

(57) ABSTRACT

A cooling unit (1) for cooling a heat-generating component, comprising- at least one inlet (5) for inflow of air (Φin) into the cooling unit and at least one outlet (7) for outflow of air (Φout) from the cooling unit, an air-moving device (30), and at least one heat sink comprising abase thermally connectable to a heat-generating component and comprising a plurality of cooling fins (54) that project from the base. The cooling unit comprises a first cooling section (51) comprising cooling fins (54) and a second cooling section (52) comprising cooling fins (54), and the first and second cooling sections form a layered configuration in relation to the first base. At least some of the cooling fins project from a first base (53) of a first heat sink (50), which base is thermally connectable to a heat-generating component. The at least one inlet (5) is arranged in one of the first and second cooling sections and the at least one outlet (7) is arranged in the other of the first and second cooling sections. The air-moving device (30) is arranged to move air between the first cooling section (51) and the second cooling section (52), whereby an inflow of air is obtained in one of the first and second cooling sections and an outflow of air is obtained in the other of the first and second cooling sections. A corresponding method for cooling is disclosed.

### TECHNICAL FIELD

The present disclosure relates to a cooling unit for cooling a heat-generating component and a method for cooling a heat-generating component.

### BACKGROUND

The thermal design often dictates the overall size and weight of the ICT (Information and Communication Technology) hardware. Thermal management of the equipment forces the designer to increase the size and weight of the product. Weight and volume can be reduced significantly by utilizing the increased heat transfer provided by a forced convection cooled design solution (e.g. by utilizing fans).

Increasing power densities is a clear trend within the ICT business. This is particularly true for board mounted components such as FPGA's (Field Programmable Gate Arrays), ASIC's (Application Specific Integrated Circuits) and CPU's (Central Processing Units). This trend clearly constitutes one of the major future challenges from a thermo-mechanical perspective. Very often the laws of physics prohibit equipment to be cooled by means of natural convection, and hence forced convection cooling solutions must be adopted to cool the equipment.

Forced convection cooling design solutions implies some constraints. There are two clear disadvantages with forced convection solutions; (1) they generate acoustic noise and (2) they have a limited lifetime. Acoustic noise and lifetime constraints are further actualized by massive 5G RAN (Radio Access Network) roll outs in residential areas as well as remote sites.

Existing forced convection cooling solutions usually consists of a fan tray mounted adjacent either to the inlet or the outlet of the unit. An example of a cooling unit with a fan mounted adjacent to a heat sink is described in US2003/0016495. Air is forced through a heat sink in one direction.

The main problem with the above mentioned design is two-fold; (1) The volume occupied by the heat sink is not optimally utilized to transfer the heat generated within the equipment and (2) the acoustic noise generated by the fans even at moderate speeds can be disturbing for humans. Hence the only way to mitigate the noise issue would be to make the product larger and heavier, i.e., larger fans and/or larger heat sink.

Another example of a cooling unit with a fan and heat sink arrangement is described in US 2002/0079086. In the latter the fan is embedded in a cavity formed in the heat sink. A third example of a cooling unit with a fan and a heat exchanger is described in U.S. 6,247,526.

### SUMMARY

It should be emphasized that the term “comprises/comprising” when used in this specification is taken to specify the presence of stated features, integers, steps, or components, but does not preclude the presence or addition of one or more other features, integers, steps, components, or groups thereof. As used herein, the singular forms “a”, “an” and “the” are intended to include the plural forms as well, unless the context clearly indicates otherwise.

It is an object of some embodiments to solve or mitigate, alleviate, or eliminate at least some of the above or other disadvantages.

According to a first aspect, the object is achieved by a cooling unit for cooling a heat-generating component, comprising at least one inlet for inflow of air into the cooling unit and at least one outlet for outflow of air from the cooling unit, an air-moving device and at least one heat sink comprising a base thermally connectable to a heat-generating component and comprising a plurality of cooling fins that project from the base. The cooling unit comprises a first cooling section comprising cooling fins and a second cooling section comprising cooling fins, and at least some of the cooling fins project from a first base of a first heat sink, which base is thermally connectable to a heat-generating component. Said first and second cooling sections form a layered configuration in relation to the first base. The at least one inlet is arranged in one of the first and second cooling sections and the at least one outlet is arranged in the other of the first and second cooling sections. The air-moving device is arranged to move air between the first cooling section and the second cooling section, whereby an inflow of air is obtained in one of the first and second cooling sections and an outflow of air is obtained in the other of the first and second cooling sections.

By cooling fin is intended any type of fin of a heat sink, which fin will take up heat from a base of the heat sink and transfer the heat by radiation to surrounding air or possibly another gas.

The cooling section having the inflow of air is thus located upstream of the air-moving device and the cooling section having the outflow of air is thus located downstream. The cooling unit can then be described as having an upstream cooling section and a downstream cooling section. Through this cooling unit is obtained that air in the upstream cooling section accumulates heat from the heat sink and this air is moved by the air-moving device to the downstream cooling section, where the air can accumulate more heat. For example, the downstream cooling section can then be the cooling section that is closer to the heat-generating component than the upstream cooling section. The cooling section that is closer to the heat-generating component will have a higher temperature than the cooling section that is further away from the heat-generating component. Thus, the air will have accumulated heat of a lower temperature in the upstream cooling section and it will be possible for the air to accumulate heat by heat transfer also in the downstream cooling section due to its higher temperature. In this way, a more efficient cooling is obtained. However, also the opposite arrangement is possible, with the upstream cooling section being the cooling section that is closer to the heat-generating component, or generally closer to where there is a higher temperature, than the downstream cooling section.

The air-moving device is then arranged to create an airflow that accumulates heat from the cooling fins in the respective cooling sections both upstream and downstream of the air-moving device.

In one example, the air-moving device comprises a fan of some kind, e.g. a centrifugal fan or an axial fan.

As mentioned, the cooling unit comprises at least one inlet for inflow of air into the cooling unit and at least one outlet for outflow of air from the cooling unit. If the cooling unit has open sides, such inlets are created anywhere where there is an air-moving device that has the effect creating an inflow of air into the cooling unit. Correspondingly, outlets are created anywhere where there is an air-moving device that has the effect creating an outflow of air from the cooling unit. However, the at least one inlet and at least one outlet may be provided at particular locations as will be described.

In one example, the air-moving device is located in a cavity formed in the at least one heat sink. The cavity may be located in either one of the first cooling section and the second cooling section, or in between the cooling sections. By this is obtained that a more compact cooling unit can be obtained. It can also be obtained that the transmission to the surroundings of acoustic noise generated by the air-moving device will be reduced when the air-moving device is located within the heat sink of the cooling unit. Furthermore, the efficiency will be improved since the air-moving device can suck in air from any direction in the upstream cooling section and exhaust air in any direction in the downstream cooling section, except for possible limitations due to the configuration of the cooling fins.

In one example, the cooling unit comprises one or more separation walls, and each separation wall is located between a part of the first cooling section and a part of the second cooling section, and thereby separate said part of the first cooling section from said part of the second cooling section. To install separation walls will improve the possibility for good heat transfer in the different cooling sections since the airflow in the different cooling sections will be more distinctly separated.

In one example, the air-moving device is located in a region of the cooling unit where there is no separation wall. The cooling unit will comprise regions where there is a separation wall as described above, and other regions where there is no separation wall in order to facilitate the installation of an air-moving device.

In one example, the cooling unit is a closed unit with the exception of the at least one inlet for inflow of air and the at least one outlet for outflow of air. This will have a noise-reducing effect and the airflow within the unit will be improved since it can be more concentrated.

In one example, the at least one inlet is arranged in a sidewall of the cooling unit, and the at least one outlet is arranged in another sidewall of the cooling unit that does not have any inlet, and vice versa. By separating inlets and outlets in this way, any turbulence created at e.g. an outlet will not disturb the airflow at an inlet, as it might if they were close together. This may also create unwanted noise. It also prevents that already heated outlet air is recirculated by being sucked into a nearby inlet.

In one example, the cooling unit comprises a second heat sink that comprises a second base thermally connectable to a heat-generating component and wherein some of cooling fins project from the second base. By this arrangement, it will be possible to cool more than one component.

It may be mentioned that in the case where there is only one heat sink, the cooling unit may be provided with a cover that covers the side opposite the first heat sink, which otherwise would be open. However, this is optional.

In one example, the cooling unit comprises a plurality of air-moving devices distributed in the cooling unit. By this, a more efficient cooling may be obtained also for larger heat-generating components.

In one example, the cooling unit comprises a plurality of first cooling sections and a plurality of second cooling sections arranged in a stacked configuration with alternating first and second cooling sections, and a plurality of air-moving devices.

According to a second aspect is provided a method for cooling a heat-generating component that is thermally connected to a cooling unit comprising at least one inlet for inflow of air and at least one outlet for outflow of air, an air-moving device and at least one heat sink. The method comprises creating a first cooling section, comprising cooling fins, upstream of the air-moving device, and a second cooling section, comprising cooling fins, downstream of the air-moving device, wherein at least some of the cooling fins project from a first base of a first heat sink, which base is thermally connected to a heat-generating component, and said first and second cooling sections forming a layered configuration in relation to the first base. The method further comprises creating an airflow through the first cooling section and through the second cooling section by moving air from the first cooling section to the second cooling section by means of operating the air-moving device and thereby cooling the heat-generating component.

The example method has advantages that correspond to what has been described above with regard to the example cooling unit.

The heat-generating component may e.g. comprise a Printed Circuit Board (PCB) or an electric or electronic component on a PCB. As an example, the heat-generating component mentioned above may also comprise a thermal interface material that has been applied to a PCB or a component thereof. The heat-generating component may be a component of ICT products.

The major advantages with the proposed solution is the possibility to have low size and low weight ICT products combined with low acoustic noise. This is crucial to meet future (and existing) demands for higher ICT data rates without causing unacceptable acoustic disturbances to people. The latter is especially (but not exclusively) important when equipment is mounted close to where people reside.

The proposed solution leverages the fact that the fans are built into the system together with a cooling air separation plate or wall that allows for the cooling air flow to accumulate a maximum amount of heat while the acoustic noise from the fans are minimized. The proposed solution also encompasses a novel approach for positioning air inlets and air outlets such as to limit air recirculation (from air outlet to air inlet), both stand-alone as well as in a stacked scenario (in any direction).

In some examples, any of the above aspects may additionally have features identical with or corresponding to any of the various features as explained above for any of the other aspects.

### BRIEF DESCRIPTION OF THE DRAWINGS

Further objects, features and advantages will appear from the following detailed description of embodiments, with reference being made to the accompanying drawings. The drawings are not necessarily to scale, emphasis instead being placed upon illustrating the example embodiments.

Elements that are the same or represent corresponding or equivalent elements have been given the same reference numbers in the different figures.

FIG. 1 is a schematic top view drawing illustrating an example of a cooling unit,

FIG. 2a is a schematic side view of the example cooling unit in FIG. 1,

FIG. 2b is a schematic side view of an alternative example,

FIG. 3a-3d illustrate schematically different examples related to the air-moving device,

FIGS. 4a-4d illustrate schematically different examples related to the location of inlets and outlets of a cooling unit,

FIG. 5a-5b illustrate schematically examples related to the heat sink, and

FIG. 6 is a diagram illustrating a method.

### DETAILED DESCRIPTION

As already mentioned above, it should be emphasized that the term “comprises/comprising” when used in this specification is taken to specify the presence of stated features, integers, steps, or components, but does not preclude the presence or addition of one or more other features, integers, steps, components, or groups thereof. As used herein, the singular forms “a”, “an” and “the” are intended to include the plural forms as well, unless the context clearly indicates otherwise.

Embodiments of the present disclosure will be described and exemplified more fully hereinafter with reference to the accompanying drawings. The solutions disclosed herein can, however, be realized in many different forms and should not be construed as being limited to the embodiments set forth herein.

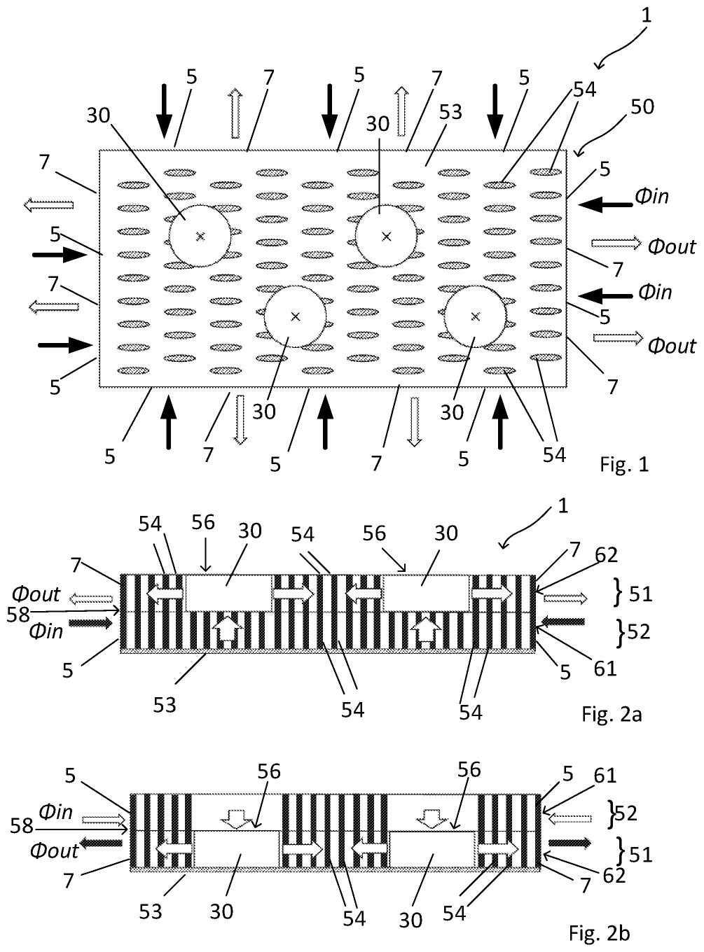

FIGS. 1 and 2a illustrate an example showing the general principles of the present disclosure. A cooling unit 1 for cooling a heat-generating component is shown. The cooling unit comprises at least one inlet 5 for inflow of air Φin into the cooling unit and at least one outlet 7 for outflow of air Φout from the cooling unit. It further comprises an air-moving device 30 and at least one heat sink 50 comprising a base 52 thermally connectable to a heat-generating component (not shown) and comprising a plurality of cooling fins 54 that project from the base. The cooling unit comprises a first cooling section 51 comprising cooling fins 54 and a second cooling section 52 comprising cooling fins 54. The first and second cooling sections 51, 52 form a layered configuration in relation to the base 53. The at least one inlet 5 is arranged in one of the first and second cooling sections and the at least one outlet 7 is arranged in the other of the first and second cooling sections. The air-moving device 30 is arranged to move air between the first cooling section 51 and the second cooling section 52, whereby an inflow of air is obtained in one of the first and second cooling sections and an outflow of air is obtained in the other of the first and second cooling sections. According to one example, the at least one heat sink comprises a first heat sink 50 comprising a first base 53 that is thermally connectable to a heat-generating component, and at least some of the cooling fins 54 of the first and second cooling sections project from the first base 53 of the first heat sink. In the illustrated example is shown a first heat sink 50 comprising a first base 53 from which cooling fins 54 project into the first and second cooling sections 51, 52. However, as will be explained later, there are examples where the cooling fins of the first heat sink only project into the first cooling section,

The example cooling unit 1 in FIG. 1 has four air-moving devices 30 distributed in the cooling unit. It should be emphasized that the number of air-moving devices may vary from one and upwards, depending on the size of the cooling unit and the heat-generating component, as well as temperature and the required cooling effect. In FIG. 1, cooling air inflow Φin, i.e. cooling air upstream of the air-moving device 30, is illustrated with plain arrows and cooling air outflow Φout, i.e. cooling air downstream of the air-moving device 30, is illustrated with filled arrows.

In the example, the cooling unit 1 has open sides and consequently inflow of air can take place anywhere around the cooling unit, where there is sufficient proximity to an air-moving device 30 that can have a suction effect on air surrounding the cooling unit. In a similar manner, outflow of heated cooling air can also take place anywhere around the cooling unit, where there is sufficient proximity to an air-moving device 30 that can blow out air. However, as will be explained later, there are other possible examples where the locations of inlets and outlets are determined in order to achieve certain effects.

In the example of FIG. 1, the cooling fins 54 are illustrated as pin fins. Naturally, the cooling fins may have other geometries and configurations and these may have an impact on the directions of inflow and outflow of air. If e.g. the cooling fins are straight fins that form ridges in a certain direction, then the airflow will of course only be possible along the direction of the fins. Examples of configurations of cooling fins are: straight, angled, V-fins, circular pin fins, non-circular pin fins, spiral shaped.

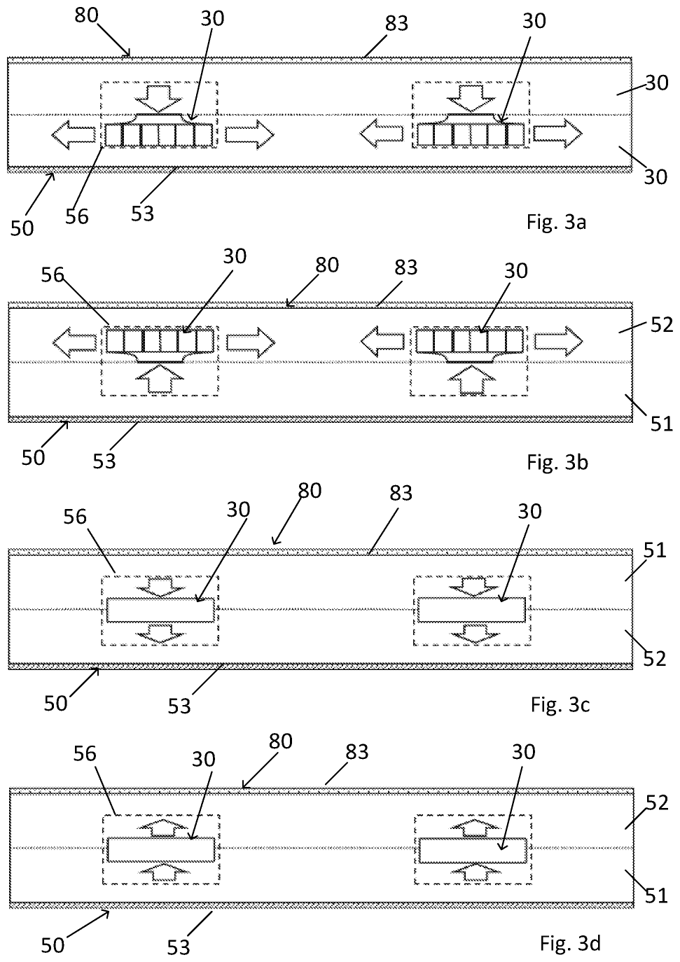

The first and second cooling sections 51, 51 are more clearly seen in FIG. 2a and in the alternative example of FIG. 2b. In these examples is also seen how the air-moving device 30 is arranged to create an airflow that accumulates heat from the cooling fins 54 in the respective cooling sections both upstream and downstream of the air-moving device 30. Cooling fins 54 are projecting from the first base 53 of the first heat sink 50. In the first cooling section 51 shown in FIG. 2a, which is closest to the base 53, the cooling fins 53 project from all over the base. However, only some of the cooling fins project also into the second cooling section 52. In the heat sink 50, in between the cooling fins 54 in the second cooling section 52 is created a cavity 56, in which the air-moving device 30 is located. The air-moving device 30 can thus be described as embedded in the heat sink 50. As mentioned before, examples of air-moving devices are centrifugal (radial) fans and axial fans. A suitable fan for the example in FIG. 2a would be a centrifugal fan as shown in FIG. 3b. The fan would be placed with its air intake side facing the first cooling section 51 upstream of the fan, and with its exhaust located in the second cooling section 52, downstream of the fan. The air intake facing the first cooling section will work to suck in air from the outside of the cooling unit, via the inlet 5, and this air will pass by the cooling fins 54 in the first cooling section 51 and absorb heat from the cooling fins on its way to the fan.

Since a centrifugal fan will blow out air at a right angle to its intake, the air that leaves the fan will be directed along the second cooling section. It will then pass by the cooling fins 54 of the second cooling section 52 and absorb heat from the cooling fins, before it is exhausted from the cooling unit via the outlet 7.

Generally, with regard to the first cooling section and the second cooling section, in this description the first cooling section will usually be the upstream cooling section and the second cooling section will usually be the downstream cooling section.

In the example of FIG. 2b, the air-moving device 30 is instead located in the cooling section 52 that is closest to the first base 53 of the heat sink 50. A suitable air-moving device 30 for this configuration would e.g. be a centrifugal fan as illustrated in FIG. 3a. The fan itself would be located in a cavity 56 of the heat sink, in the second cooling section. Due to this, the second cooling section cannot have cooling fins where the air-moving device is located. In analogy with the example of FIG. 2a, the fan would be placed with its air intake side facing the first cooling section 51 upstream of the fan, and with its exhaust located in the second cooling section 52, downstream of the fan. The air intake facing the first cooling section will work to suck in air from the outside of the cooling unit, via the inlet 5, and this air will pass by the cooling fins 54 in the first cooling section 51 and absorb heat from the cooling fins on its way to the fan. Since a centrifugal fan will blow out air at a right angle to its intake, the air that leaves the fan will be directed along the second cooling section 52. It will then pass by the cooling fins 54 of the second cooling section 52 and absorb heat from the cooling fins, before it is exhausted from the cooling unit via the outlet 7.

The examples of FIGS. 1, 2a and 2b all show four air-moving devices, but the number can vary, as mentioned before.

In one example, the cooling unit 1 comprises one or more separation walls 58, and each separation wall is located between a part 61 of the first cooling section 51 and a part 62 of the second cooling section 52, and thereby separate said part of the first cooling section from said part of the second cooling section. The separation wall/walls is an optional element. The examples of FIGS. 2a and 2b show such separation walls 58. In the example, the separation walls are located between cooling fins of the first cooling section and cooling fins of the second cooling section. It is an advantage to distinctly separate the first and second cooling sections whenever possible in order to separate the airflows in the respective cooling section. The airflows in the respective cooling section may disturb each other or mix, which might be detrimental to the desired cooling effect. However, there is no separation wall between the cooling sections 51, 52 where the air-moving device 30 is located, since such a separation wall would prevent the desired movement of air. Thus, the cooling unit comprises regions that comprise a separation wall and regions with no separation wall. The air-moving device 30 is located in a region of the cooling unit 1 where there is no separation wall 58.

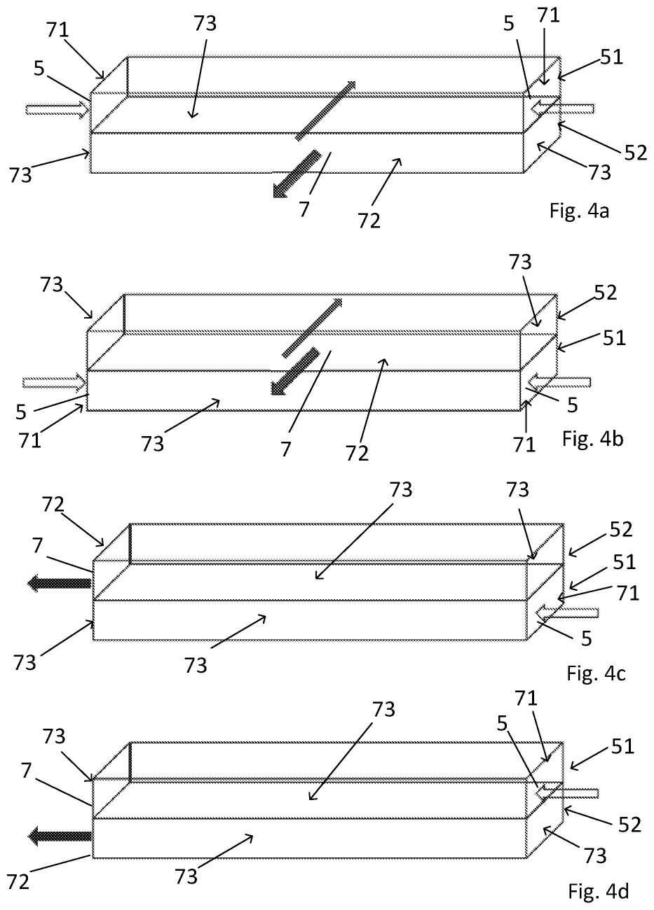

In one example, the cooling unit comprises at least one inlet for inflow of air into the cooling unit and at least one outlet for outflow of air from the cooling unit. As described before, the cooling unit may have open sides such that there will actually be inlets for inflow of air more or less anywhere in the sides, and there may be outlets for outflow of air more or less anywhere in the sides. However, it is also possible to only have inlets and outlets at dedicated locations. Different examples of this are shown in FIGS. 4a-4d.

In one example, the cooling unit 1 is a closed unit with the exception of at least one inlet 5 for inflow of air and at least one outlet 7 for outflow of air. Examples of such a closed cooling unit are shown in the schematic FIGS. 4a-4d. According to these examples, the at least one inlet 5 is arranged in a sidewall of the cooling unit, and the at least one outlet 7 is arranged in another sidewall of the cooling unit that does not have any inlet, and vice versa. The at least one inlet is located in a sidewall of one of the first and second cooling sections, and the at least one outlet is located in a sidewall of the other of the first and second cooling sections.

With reference to FIGS. 4a-4d, the sidewalls having one or more inlets 5 will be designated inlet sidewalls 71 and the sidewalls having one or more outlets 7 will be designated outlet sidewalls 72. By inlet sidewall and outlet sidewall should be understood that such a sidewall may have one inlet/outlet or several inlets/outlets. The sidewall may be totally open or it may comprise closed wall parts with openings made for inlets or outlets. The sidewalls that do not have inlets or outlets will generally be closed walls 73. Some walls will be hidden in the figures, but then an arrow will help indicate if it is an inlet or outlet sidewall.

In the example in FIG. 4a, the first cooling section 51 comprises an inlet sidewall 71 at both of the short sides of the cooling unit. In this example, the first cooling section 51 is located above the second cooling section 52. The second cooling section 52 comprises an outlet sidewall 72 on both of the long sides of the cooling unit. Thus the inlets 5 and the outlets 7 are located on different sides, and the inlets are located at a right angle in relation to the outlets. The other sides of the cooling unit are closed sidewalls 73. This example of a cooling unit can be achieved e.g. by means of a centrifugal fan as in FIG. 3a. By closing of the short sides in the second cooling section 52, the outflow air will be directed towards the long sides, i.e. the outlet sidewalls 72.

In the example in FIG. 4b, the first cooling section 51 comprises an inlet sidewall 71 at both of the short sides of the cooling unit. Here the first cooling section 51 is located below the second cooling section 52. The second cooling section 52 comprises an outlet sidewall 72 on both of the long sides of the cooling unit. Thus, the inlets 5 and the outlets 7 are located on different sides, and the inlets are located at a right angle in relation to the outlets. The other sides of the cooling unit are closed sidewalls 73. This example of a cooling unit can be achieved e.g. by means of a centrifugal fan as in FIG. 3b. By closing of the short sides in the second cooling section 52, the outflow air will be directed towards the long sides, i.e. the outlet sidewalls 72.

In the example in FIG. 4c, the first cooling section 51 comprises an inlet sidewall 71 at one of the short sides of the cooling unit. Here the first cooling section 51 is located below the second cooling section 52. The second cooling section 52 comprises an outlet sidewall 72 at one of the other of the short sides of the cooling unit, i.e. the short side opposite the inlet sidewall 71. Thus, the inlets 5 and the outlets 7 are located on different sides. The other sides of the cooling unit are closed sidewalls 73. This example of a cooling unit can be achieved e.g. by means of a centrifugal fan as in FIG. 3b or alternatively FIG. 3d. By only having an inlet 5 in one of the short sides of the first cooling section 51, the intake of air will have to be from that side. By only having an outlet 7 in one of the short sides of the second cooling section 52, the outflow air will be directed towards that short side, i.e. the outlet sidewall 72.

FIG. 4d shows an example that is identical to FIG. 4c, with the exception that the first cooling section 51 comprising the inlet 5 is located closest to the base 53, while the second cooling section 52 is located on top of the first cooling section 51. Thus, instead of having air-moving devices as in FIG. 3b or 3d, the air-moving devices may be of the types shown in FIG. 3a or 3c.

With regard to FIGS. 4a-4d, naturally, the inlets 5 and outlets 7 may swop places such that the inlets are on the long side and the outlets on the short side. Also, there is no limitation with regard to the actual geometry of the cooling unit. It may e.g. be square or round. The effect that is aimed at is that inlets and outlets preferably are provided on opposing “sides” or perpendicular to each other, or at another angle. By separating inlets and outlets in this way, any turbulence created at e.g. an outlet will not disturb the airflow at an inlet, as it might if they were close together. This may also create unwanted noise. It also prevents that already heated outlet air is recirculated by being sucked into a nearby inlet.

In one example, the cooling unit may be provided with a cover on the side opposite the first base of the first heat sink in order to further enclose the cooling unit. This will contribute to control the airflow in an improved manner. This is optional.

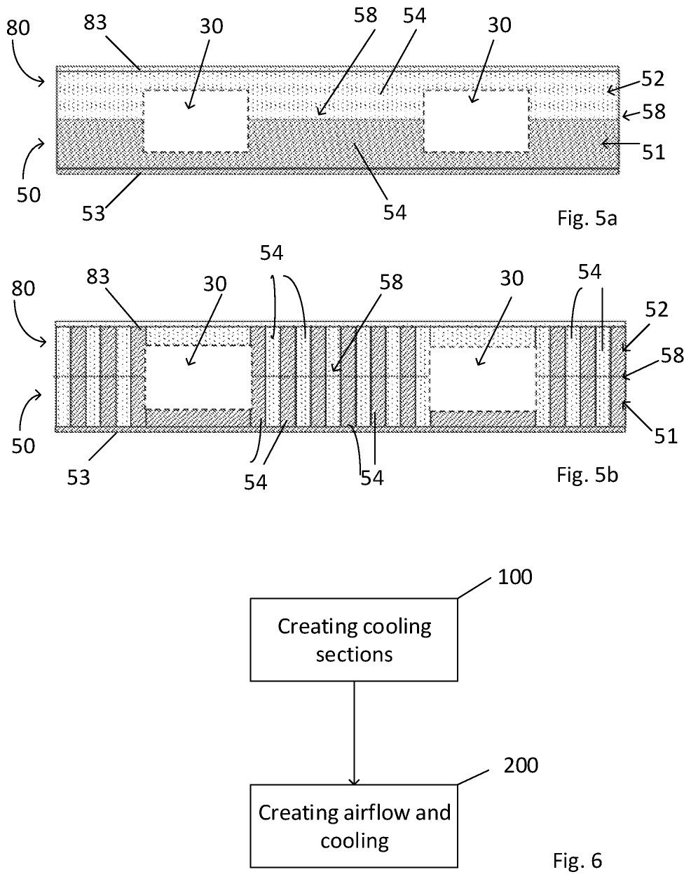

In one example, the cooling unit comprises a second heat sink 80 that comprises a second base 83 thermally connectable to another heat-generating component and some of the cooling fins 54 project from the second base of the second heat sink. This is schematically illustrated in FIGS. 3a-3d, and further in FIGS. 5a and 5b. To have a second heat sink is optional.

In one example, the cooling fins of the first cooling section 51 project from the first base 53 and the cooling fins of the second cooling section 52 project from the second base 83, as is illustrated in FIGS. 5a. Here, the cooling fins of the first heat sink 50 only extend in the first cooling section 51 and the cooling fins of the second heat sink 80 only extend in the second cooling section 52. In this context the first cooling section may be upstream the air-moving device and the second cooling section may be downstream, or vice versa.

In one example, shown in FIG. 5b, the cooling fins 54 projecting from the first base 53 extend into both the first cooling section 51 and the second cooling section 52, and cooling fins 54 projecting from the second base 80 extend into both the first cooling section 51 and the second cooling section 52. The cooling fins of the respective first and second heat sink may so to speak be overlapping in the cooling sections. Also in this context the first cooling section may be upstream the air-moving device and the second cooling section may be downstream, or vice versa. Also other configurations of the cooling fins are conceivable.

In FIGS. 5a and 5b is also illustrated an optional separation wall 58.

If there are two heat sinks, the air-moving device may be located in a cavity in one of the heat sinks, or a cavity that is formed partly in one heat sink and partly in the other heat sink.

In one example, the cooling unit 1 comprises a plurality of air-moving devices 30 distributed in the cooling unit. This has already been described and shown in the figures.

In one example, the cooling unit comprises a plurality of first cooling sections and a plurality of second cooling sections arranged in a stacked configuration with alternating first and second cooling sections, and a plurality of air-moving devices. By having a stacked configuration an increased cooling capacity can be obtained.

The described cooling unit as such, may also be made stackable such that one cooling unit is stacked on top of another with a heat-generating component between each cooling unit.

With regard to FIGS. 3a-3d, different air-moving devices are schematically shown and their possible locations within a cooling unit. In the shown examples there are two heat sinks 50, 80, but the same configurations also apply to a cooling unit having only one heat sink. Some have already been described above. FIGS. 3a and 3b show centrifugal fans, and FIGS. 3c and 3d shows examples using radial fans. A radial fan is suitably located in a cavity 56 that is formed partly in the first cooling section 51 and partly in the second cooling section 52. The fan is so to speak arranged inbetween the cooling sections. When using a radial fan, the fan does no itself change the direction of the airflow when moving air from one side to the other. Instead the direction of the inflow of air and outflow of air is determined by the location of inlets and outlets and possible closed walls of the cooling unit.

According to a second aspect is described a method, see FIG. 6, for cooling a heat-generating component that is thermally connected to a cooling unit comprising at least one inlet 5 for inflow of air Φin and at least one outlet 7 for outflow of air Φout, an air-moving device 30, and at least one heat sink, The method comprises creating 100 a first cooling section 51 comprising cooling fins 54 upstream of the air-moving device, and a second cooling section 52, comprising cooling fins 54, downstream of the air-moving device, wherein at least some of the cooling fins project from a first base 53 of a first heat sink 50, which base is thermally connected to a heat-generating component, and said first and second cooling sections forming a layered configuration in relation to the first base.

The method further comprises creating 200 an airflow through the first cooling section and through the second cooling section by moving air from the first cooling section to the second cooling section by means of operating the air-moving device and thereby cooling the heat-generating component.

As indicated by FIG. 1 one solution is that a heat sink that allows for the cooling air to flow in any direction in the horizontal (i.e. xy-plane) is utilized. As indicated by FIG. 1 radial fans are built into the system, however axial fans could also be used in the system. The fan pulls the air through the upper part of the heat sink and pushes the air out at the lower part of the heat sink (i.e. the part closest to the base plate) allowing for the cooling air to transfer heat both upstream and downstream the fans. The upper and lower parts of the heat sink may be separated by a plate or wall (cooling airflow separator).

Generally, all terms used herein are to be interpreted according to their ordinary meaning in the relevant technical field, unless a different meaning is clearly given and/or is implied from the context in which it is used.

Reference has been made herein to various embodiments. However, a person skilled in the art would recognize numerous variations to the described embodiments that would still fall within the scope of the claims.

For example, the method embodiments described herein discloses example methods through steps being performed in a certain order. However, it is recognized that these sequences of events may take place in another order without departing from the scope of the claims. Furthermore, some method steps may be performed in parallel even though they have been described as being performed in sequence. Thus, the steps of any methods disclosed herein do not have to be performed in the exact order disclosed, unless a step is explicitly described as following or preceding another step and/or where it is implicit that a step must follow or precede another step.

Any feature of any of the embodiments disclosed herein may be applied to any other embodiment, wherever suitable. Likewise, any advantage of any of the embodiments may apply to any other embodiments, and vice versa.

Hence, it should be understood that the details of the described embodiments are merely examples brought forward for illustrative purposes, and that all variations that fall within the scope of the claims are intended to be embraced therein.

1. A cooling unit for cooling a heat-generating component, comprising:
at least one inlet for inflow of air (Φin) into the cooling unit and at least one outlet for outflow of air (Φout) from the cooling unit;
an air-moving device; and
at least one heat sink comprising a base thermally connectable to a heat-generating component and comprising a plurality of cooling fins that project from the base, wherein
the cooling unit comprises a first cooling section comprising cooling fins and a second cooling section comprising cooling fins, and at least some of the cooling fins project from a first base of a first heat sink, which first base is thermally connectable to a heat-generating component,
the first and second cooling sections form a layered configuration in relation to the first base,
the at least one inlet is arranged in one of the first and second cooling sections and the at least one outlet is arranged in the other of the first and second cooling sections, and
the air-moving device is arranged to move air between the first cooling section and the second cooling section, whereby an inflow of air is obtained in one of the first and second cooling sections and an outflow of air is obtained in the other of the first and second cooling sections.

2. The cooling unit of claim 1, wherein the air-moving device is arranged to create an airflow that accumulates heat from cooling fins in the respective cooling sections both upstream and downstream of the air-moving device.

3. The cooling unit of claim 1, wherein the air-moving device is located in a cavity formed in the at least one heat sink.

4. The cooling unit of claim 1, wherein it comprises one or more separation walls, and each separation wall is located between a part of the first cooling section and a part of the second cooling section, and thereby separate said part of the first cooling section from said part of the second cooling section.

5. The cooling unit of claim 4, wherein the air-moving device is located in a region of the cooling unit where there is no separation wall.

6. The cooling unit of claim 1, wherein it is a closed unit with the exception of the at least one inlet for inflow of air (Φin) and the at least one outlet for outflow of air (Φout).

7. The cooling unit of claim 6, wherein the at least one inlet is arranged in a sidewall of the cooling unit, and the at least one outlet is arranged in another sidewall of the cooling unit that does not have any inlet, and vice versa.

8. The cooling unit of claim 1, wherein it comprises a second heat sink that comprises a second base thermally connectable to a heat-generating component and wherein some of the cooling fins project from the second base.

9. The cooling unit of claim 1, wherein it comprises a plurality of air-moving devices distributed in the cooling unit.

10. The cooling unit of claim 1, wherein the cooling comprises a plurality of first cooling sections and a plurality of second cooling sections arranged in a stacked configuration with alternating first and second cooling sections, and a plurality of air-moving devices.

11. A method for cooling a heat-generating component that is thermally connected to a cooling unit comprising: at least one inlet for inflow of air (Φin), at least one outlet for outflow of air (Φout), an air-moving device, and at least one heat sink, the method comprising:
creating a first cooling section comprising cooling fins upstream of the air-moving device, and a second cooling section, comprising cooling fins, downstream of the air-moving device, wherein at least some of the cooling fins project from a first base of a first heat sink, which base is thermally connected to a heat-generating component, and said first and second cooling sections forming a layered configuration in relation to the first base; and
creating an airflow through the first cooling section and through the second cooling section by moving air from the first cooling section to the second cooling section by means of operating the air-moving device and thereby cooling the heat-generating component.
